(19) United States
(12) Patent Application Publication
(10) Pub. No.: US 2017/0366164 A1
(43) Pub. Date: Dec. 21, 2017

(54) RADIO FREQUENCY MULTIPLEXERS

(71) Applicant: Resonant Inc., Santa Barbara, CA (US)

(72) Inventor: Gregory L. Hey-Shipton, Santa Barbara, CA (US)

(21) Appl. No.: 15/399,441

(22) Filed: Jan. 5, 2017

Related U.S. Application Data
(60) Provisional application No. 62/350,549, filed on Jun. 15, 2016.

(51) Int. Cl. H03H 9/54; H03H 9/52; H01P 5/16

(52) U.S. Cl. CPC H03H 9/54; H01P 5/16; H03H 9/52

(57) ABSTRACT

There are disclosed radio frequency multiplexers and methods of designing radio frequency multiplexers. A radio frequency multiplexer includes three or more band-pass filters having respective passbands, each band-pass filter comprising two or more acoustic resonators. A first end of each of the three or more band-pass filters is connected to a respective branch port. A second end of each of the three or more band-pass filters is connected to a common node without an intervening phasing network. A shunt reactive element connected between the common node and ground.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### RELATED APPLICATION INFORMATION

This patent claims priority from provisional patent application 62/350,549, filed Jun. 15, 2016, titled RADIO FREQUENCY MULTIPLEXERS.

### BACKGROUND

### Field

This disclosure relates to radio frequency (RF) filters incorporating acoustic resonators, and specifically to multiplexers to combine and separate different RF bands for use in communications equipment.

### Description of the Related Art

A variety of RF filters can be implemented using acoustic resonators such as surface acoustic wave (SAW) resonators, bulk acoustic wave (BAW) resonators, film bulk acoustic resonators (FBAR), thin film bulk acoustic (TFBAR) resonators, and other resonators based on acoustic waves. Filters implemented using acoustic resonators include band pass filters, band reject filters, duplexers, and multiplexers.

In this application, the term “multiplexer” refers to a device that connects multiple RF filters to a common connection node. Commonly, a multiplexer may be used to connect multiple RF band-pass filters to a common antenna. The pass-bands of these filters may be different from each other and may include one or more transmit frequency bands and/or one or more receive frequency bands. Less commonly, a multiplexer may be used to connect multiple antennas to a single transceiver. Multiplexers may be categorized by the number of filters and/or the number of pass-bands. For example, a four-band multiplexer contains four band-pass filters having four different pass-bands. A duplexer is two-band multiplexer that allows simultaneous transmission in a first frequency band and reception in a second frequency band (different from the first frequency band) using a common antenna.

Filters commonly incorporate more than one acoustic resonator. For example, FIG. 1 shows a schematic diagram of an exemplary two-port filter 100 incorporating 10 acoustic resonators, labeled X1 through X10. The filter 100 may be, for example, a transmit band pass filter or a receive band pass filter for incorporation into a communications device. The filter 100 is bidirectional. Either Port 1 or Port 2 may be used as the input to the filter and the other port used as the output. An acoustic filter commonly includes “series” resonators connected in series between two ports of the filter circuit and “shunt” resonators, one end of which is connected to ground. The filter 100 includes five series resonators (X1, X3, X5, X7, and X9) connected in series between an input (Port 1) and an output (Port 2). The filter 100 includes four shunt resonators (X2, X4, X6, and X8) connected between junctions of adjacent series resonators and ground. The filter 100 includes a fifth shunt resonator X10 connected between port 2 and ground. The filter 100 may be described as terminating in a series resonator (X1) at the end connected to port 1, and terminating in a shunt resonator (X10) at the end connected to port 2. Other filters may terminate in either a series resonator or a shunt resonator at both ends. The use of ten acoustics resonators, five series resonators, and five shunt resonators is exemplary. A filter may include more or fewer than ten acoustic resonators and a different arrangement of series and shunt resonators. A filter may include other components, such as capacitors and/or inductors, in addition to acoustic resonators.

The ten resonators X1-X10 may be SAW, BAW, FBAR, TFBAR, or other types of acoustic resonators or combinations thereof. Each of the ten resonators X1-X10 may have a corresponding resonant frequency, f1-f10. Acoustic resonators may have more than one resonance. It is common practice to define the “resonant frequency” as the motional resonance of an acoustic resonator. The resonant frequencies f1-f10 may all be different. The resonant frequencies of some of the ten resonators X1-X10 may be the same. Typically, the resonant frequencies f2, f4, f6, f8, f10 of the shunt resonators may be offset from the resonant frequencies f1, f3, f5, f7, f9 of the series resonators.

The filter 100 may be, for example, a band-pass filter designed to meet a particular set of requirements. For example, the filter 100 may be designed to provide less than a specified passband insertion loss and a specified return loss over a respective passband and more than a specified stopband insertion loss over one or more stopbands. Typically, the filter 100 is designed under the assumption that an input to each filter is driven by a nominal source impedance R_{S} and that the output of each filter drives a nominal load impedance R_{L}. R_{S} and R_{L} are typically, but not necessarily, 50 ohms, and need not be the same at both ports of each band-pass filter. The performance of the filter 100 depends, to some extent, on the source and load impedances. The filter 100 may not meet the set of requirements if the source or load impedance departs substantially from the nominal values of R_{S} and R_{L}.

FIG. 2 shows a block diagram of conventional four-channel multiplexer 200 including four filters 210, 220, 230, 240 coupled to a common node 250 through respective phasing networks 215, 225, 235, 245. Each of the filters 210, 220, 230, 240 may be implemented using acoustic resonators. One or more of the filters 210, 220, 230, 240 may be, for example, the filter 100 of FIG. 1.

The multiplexer 200 has four branch ports (Port 1 through Port 4) connected to respective filters and a common port connected to the common node 250. Each of the filters 210, 220, 230, 240 is a two port network. To avoid confusion between “ports” of the multiplexer and “ports” of the individual filters, the filter ports will be referred to as “ends” in this description. Thus, in the multiplexer 200, a first end of each of the filters 210, 220, 230, 240 is connected to a respective branch port, and a second end of each filter is connected to the respective phasing networks 215, 225, 235, 245.

The phasing networks 215, 225, 235, 245 may be required to maintain good electrical performance when the individual filters are coupled to the common node 250. “Phasing network” is the term commonly used to describe the circuitry used to connect multiple filters to a common junction. In this description, a “phasing network” is a network of one or more components intended to introduce a fixed or frequency dependent phase shift. A phasing network may also be referred to as an “impedance matching network.” With lossless filters circuits, each filter 210, 220, 230, 240 approximately presents a unity reflection coefficient to the other filters, but with a phase between an open circuit (0°) and a short circuit)(+/−180°. To a first approximation, each phasing network 215, 225, 235, 245 adjusts the phase presented by the respective filter 210, 220, 230, 240 to be substantially an open circuit at the pass band frequencies of the other filters. Each phasing network 215, 225, 235, 245 may be by, for example, a length of transmission line, a capacitor, an inductor, or combinations of reactive components. In addition to the phasing networks 215, 225, 235, 245, a shunt reactance (not shown in FIG. 2) may be required at the common node. The components of the phasing networks 215, 225, 235, 245 may be lumped, distributed, monolithic, or some combination thereof. The phasing networks 215, 225, 235, 245 contribute to the size, cost, and insertion loss of the multiplexer 200.

### DESCRIPTION OF THE DRAWINGS

FIG. 1 is a schematic diagram of an exemplary RF filter.

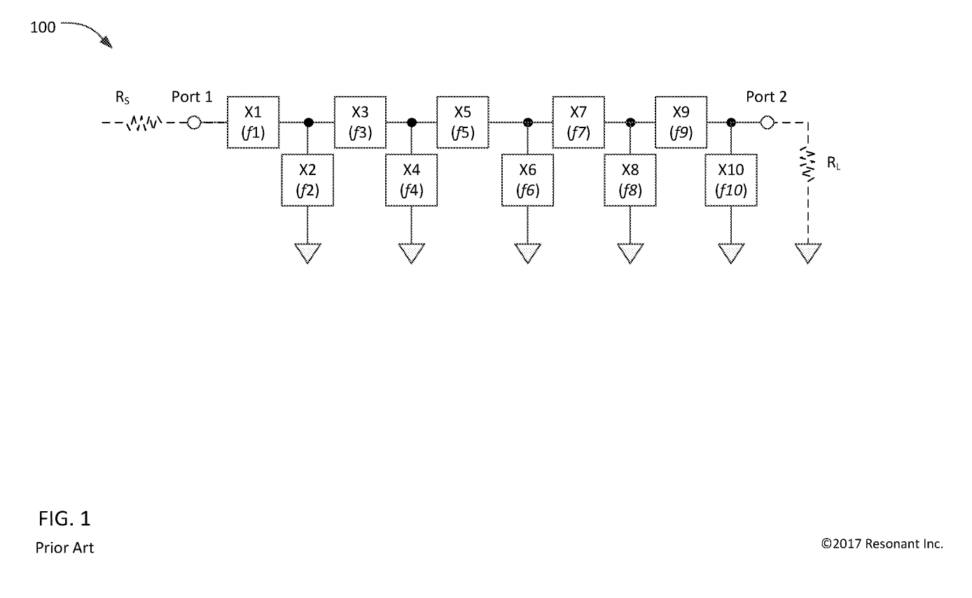

FIG. 2 is a block diagram of a conventional four-band RF multiplexer.

FIG. 3 is a flow chart of a process for designing RF multiplexers.

FIG. 4 is a schematic diagram of a four-band RF multiplexer.

FIG. 5 is a block diagram of another four-band RF multiplexer.

FIG. 6 is a graph of the insertion loss of the four channels of an exemplary four-band RF multiplexer.

FIG. 7 is another graph of the insertion loss of the four channels of the exemplary four-band RF multiplexer.

FIG. 8 is a graph of the return loss at a common port of the exemplary four-band RF multiplexer.

FIG. 9 is a graph of the return loss at four branch ports of the exemplary four-band RF multiplexer.

Throughout this description, elements appearing in figures are assigned three-digit reference designators, where the most significant digit is the figure number where the element is first shown and the two least significant digits are specific to the element. An element that is not described in conjunction with a figure may be presumed to have the same characteristics and function as a previously-described element having the same reference designator.

### DETAILED DESCRIPTION

Description of Methods

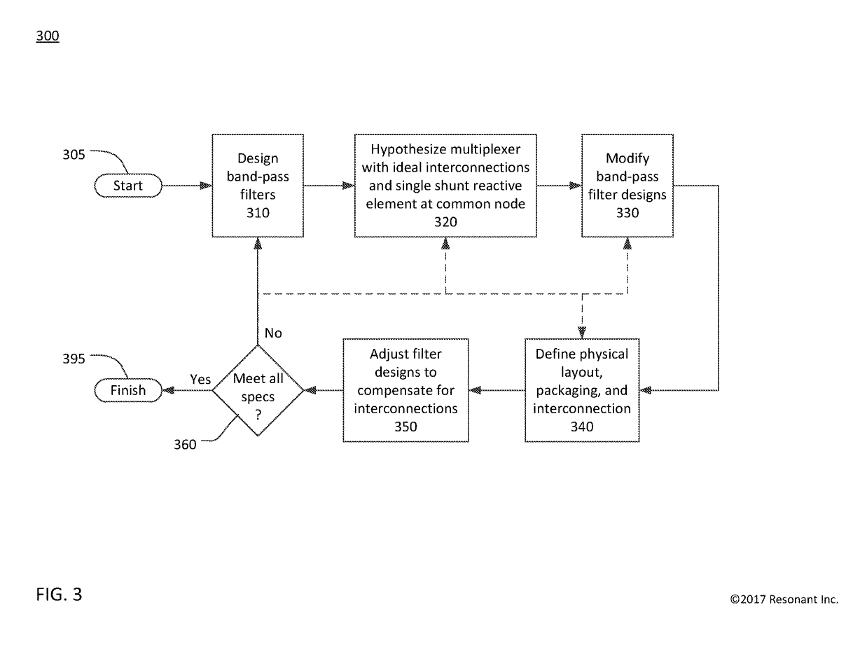

FIG. 3 is a flow chart of a process 300 for designing a multiplexer. The process 300 starts at 305 with a set of specifications for a multiplexer having three or more channels, where each channel comprises a respective band-pass filter connected between a respective branch port and a common port. Each branch port is typically an input or an output of the multiplexer, and the common port is both an input and an output. Typically, the specifications for a multiplexer include definition of a passband for each channel of the multiplexer. The specification may also include, for example, a maximum insertion loss from the respective branch port and the common port over the passband of each channel, minimum return loss at each port, and minimum isolation between various pairs of ports. The process 300 ends at 395 with a design that, based on simulation and analysis results, meets the specifications. The process 300 may be partially cyclic, with some or all of the actions from 310 to 360 repeated as necessary to iteratively optimize the design.

Typically, a multiplexer is designed under the assumption that each branch port and the common port are driven from or loaded by a respective nominal impedance. The nominal impedance is typically, but not necessarily, 50 ohms, and need not be the same at all ports of the multiplexer.

At 310, a set of band-pass filters, one for each channel of the multiplexer, are designed using any suitable design methodology. Each band-pass filter may be designed to meet a set of requirements derived from the specifications for the multiplexer. For example, each band-pass filter may be designed to provide less than a specified passband insertion loss and a specified return loss over a respective passband and more than a specified stopband insertion loss over one or more stopbands.

The band-pass filters may be designed at 310 with the aid of a circuit analysis software tool using Butterworth-Van Dyke (BVD) models for resonators. A BVD model is a circuit model that represents a resonator as a group of lumped circuit elements. The band-pass filters may be designed at 310 using physical models and an electromagnetic field software analysis tool. The band-pass filters may be designed at 610 using a combination of circuit analysis and EM analysis tools. Each band-pass filter designed at 610 typically includes a plurality of resonators, and may also include reactive components such as inductors and capacitors. Each band-pass filter may be designed with the assumption that one end of the filter is driven by a nominal source impedance and that a second end of the filter drive a nominal load impedance. The nominal source and load impedances are typically, but not necessarily, 50 ohms, and need not be the same at all ports of the multiplexer.

For ease of discussion, the end of each band-pass filter to be connected to a branch port of the multiplexer is defined as the first end of the filter, and the end of each filter that will be connected to a common node within the multiplexer is defined as the second end. Further, for reasons to be discussed subsequently, the second end of each band-pass filter designed at 310 terminates with a series resonator.

At 320, the band-pass filters designed at 310 are combined to form a hypothetical multiplexer. More correctly, the models of the band-pass filters from 310 are combined to form a model of the hypothetical multiplexer. In the hypothetical multiplexer, the second end of each band-pass filter from 310 is connected to a common node by an “ideal” interconnect, which is to say an interconnect that does not have resistance or reactance and does not introduce a phase shift between the filter and the common node.

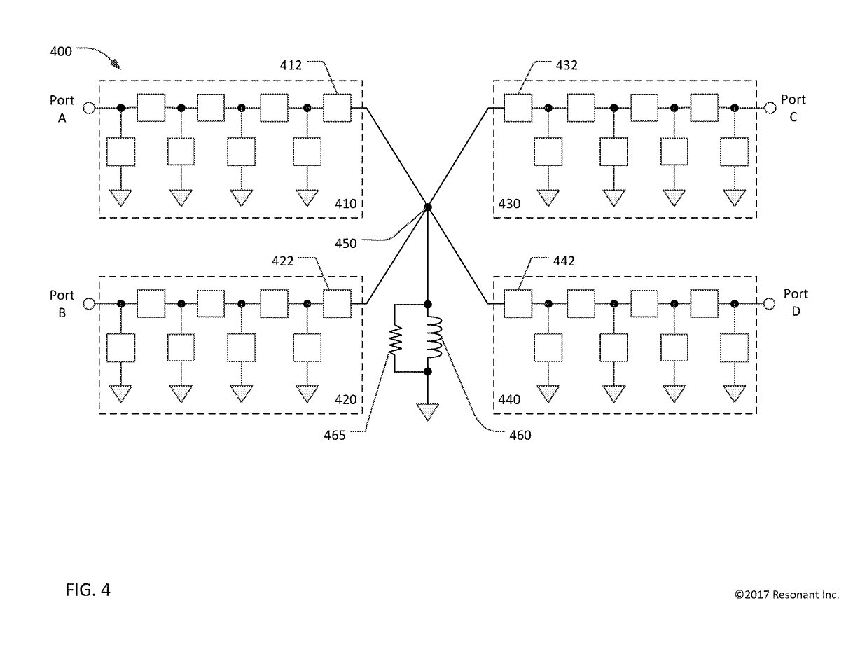

FIG. 4 is a schematic diagram of an exemplary four-band multiplexer 400 as hypothesized at 320 in the process 300. The exemplary four-band multiplexer 400 includes four band-pass filters 410, 420, 430, 440. A first end of each band-pass filter 410, 420, 430, 440 is connected to a respective branch port (Port A, Port B, Port C, and Port D) and a second end of each band-pass filter is coupled to a common node 450 with ideal connections. The second end of each band pass filter 410, 420, 430, 440 terminates in a respective series resonator 412, 422, 432, 442 that connects to the common node 450.

In the hypothetical multiplexer 400, the common node 450 is coupled (also with ideal connections) to a nominal load 465 having predetermined impedance (such as 50 ohms) and a single shunt reactive element 460 connected from the common node to ground. The shunt reactive element 460 is selected to have a positive reactance at a predetermined frequency, which may be, for example, the approximate geometric center frequency of the passbands of the band-pass filters. Thus the shunt reactive element 460 can be considered an inductor but may also have some capacitive properties. Persons skilled in the art of RF design will understand that the shunt reactive element 460 may need to be modeled as a mixture of both inductive and capacitive properties.

In the hypothetical multiplexer 400, the second end of each band-pass filter is connected, via the common node 450, to a plurality of elements in parallel including the nominal load, the shunt reactive element 460, and the second ends of each of the other band-pass filters. Thus the second end of each band-pass filter is coupled to a frequency-dependent complex impedance, which is substantially different from the nominal resistive load or source impedance assumed during the design of the band-pass filters at 310. This difference in impedance affects the performance of the band-pass filters, such that some or all of the band-pass filters in the hypothetical multiplexer 400 may no longer satisfy the requirements placed on the band-pass filters at 310.

In the exemplary multiplexer 400, each band-pass filter 410, 420, 430 and 440 arbitrarily includes eight resonators. A multiplexer may include more or fewer than four band-pass filters. Each band-pass filter may include more or fewer than eight resonators or nine or more resonators. Each band-pass filter includes a series resonator at the end of the filter connected to the common mode. Each filter will typically also include at least one shunt resonator and at least one additional series resonator. The number of shunt and series resonators in each filter need not be the same.

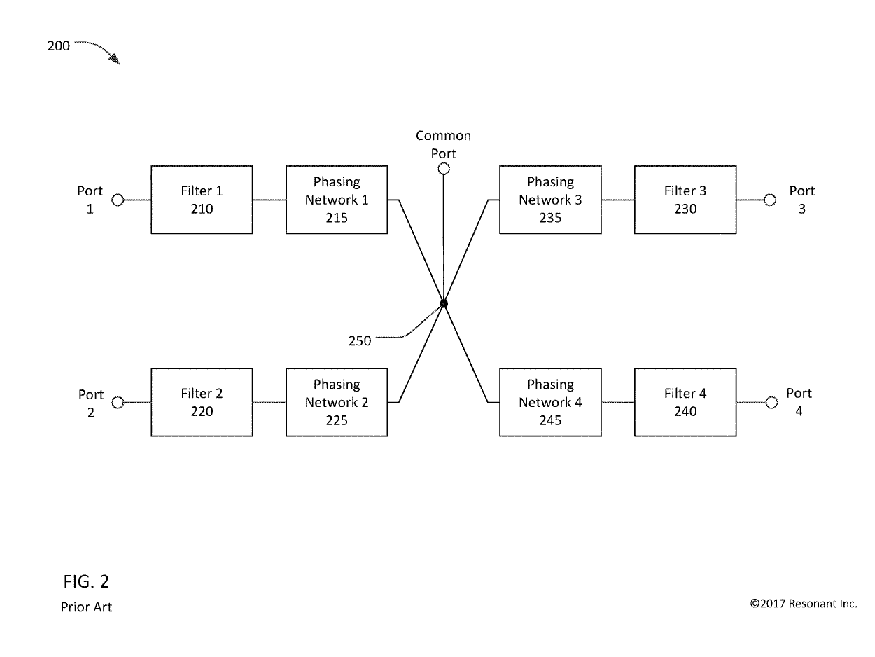

Referring back to FIG. 3, the designs of some or all of the band-pass filters may be modified at 330 to minimize the effects of each band-pass filter on the performance of the other band-pass filters in the multiplexer. As previously discussed with respect to FIG. 2, each band-pass filter approximately presents a unity reflection coefficient to the other band-pass filters, but with a phase between an open circuit (0°) and a short circuit (+/−180°. To a first approximation, the effects of each band-pass filter on the other band-pass filters can be minimized if the second end of each band-pass filter appears, as seen from the common node, to be substantially an open circuit at the passband frequencies of the other band-pass filters. In this context, “substantially” has its normal meaning of “for the most part, essentially.” A filter port may be considered to be substantially an open circuit if the presence of the filter port does not degrade the performance of the other filters in a multiplexer to the extent that the other filters fail to meet respective requirements. In the multiplexer 200 of FIG. 2, this objective is satisfied, to the extent possible, by frequency-dependent phase shifting networks 215, 225, 235, 245 coupled between some or all of the band-pass filters 210, 220, 230, 240 and the common node 250. In the multiplexer 400 of FIG. 4, phase shifting networks are not required because the requirement for the second end of each band-pass filter to appear as substantially an open circuit at the passband frequencies of the other band-pass filters is satisfied by the modified band-pass filter designs from 330.

Modifying the band-pass filter designs at 330 can be considered, in simplified terms, as absorbing phase shifting networks that would otherwise be required (for example the phase shifting networks 215, 225, 235, 245 of FIG. 2) into the terminating series resonators (for example 412, 422, 432, 442 in FIG. 4) at the second end of each band-pass filter. Changes in the terminating series resonators may necessitate changes to other resonators within each band-pass filter at 330. A change in the value of the shunt reactive element and/or the design of the terminating series resonator of one band-pass filter effectively modifies the load on the other bandpass filters. Thus a change in design of the terminating series resonator of one band-pass filter may affect, to at least some extent, the performance of some or all of the other band-pass filters. Thus the design modifications at 330 may be performed in an iterative manner until all of the band-pass filters in the multiplexer meet the respective requirements from 310.

At 340, the hypothetical multiplexer, including the modified band-pass filter designs from 330, is converted into a physical design. The physical design includes layout, packaging, and interconnections. For example, at 340, the resonators of the band-pass filters may be laid out on one or more piezoelectric chips. These piezoelectric chips may then be flip-chip mounted to one or more circuit cards within one or more packages, which are in turn mounted to a printed wiring board. The band-pass filters may be interconnected by a combination of traces on the piezoelectric chip(s), solder bumps between the chip(s) and the circuit card(s), traces on the circuit card(s) within the package(s), solder bump or other connections between the package(s) and the printed wiring board, and traces on the printed wiring board. To provide flexibility, the shunt reactive element may be a chip component on the printed wiring board external to the package(s) containing the band-pass filters.

At 350, a circuit model of the layout, packaging, and interconnections is derived based on the physical design from 340. Preferably the length of the interconnections in the physical design are small compared to the wavelength at the frequency of operation of the multiplexer, such that the interconnections can be modeled as small inductances rather than transmission lines. The layout/package/interconnection circuit model is then combined with the multiplexer circuit model from 330. The combined model is then evaluated at 350 using circuit simulation and/or electromagnetic modeling and the band-pass filters design are adjusted as needed to compensate for the interconnections. Compensating for the interconnections may be accomplished, in overly simplified terms, by removing inductance from the terminating series resonators in each band-pass filter to offset the inductance of the interconnections.

At 360, a determination is made whether or not the multiplexer design from 350 meets the set of specifications from 305. If a determination is made that the design meets the specifications (“yes” at 360), the process 300 ends at 395. If a determination is made that the design does not meet the specifications, the process 300 may repeat from 310, 320, 330, or 340 iteratively until a design meeting all of the specifications is established.

Description of Apparatus

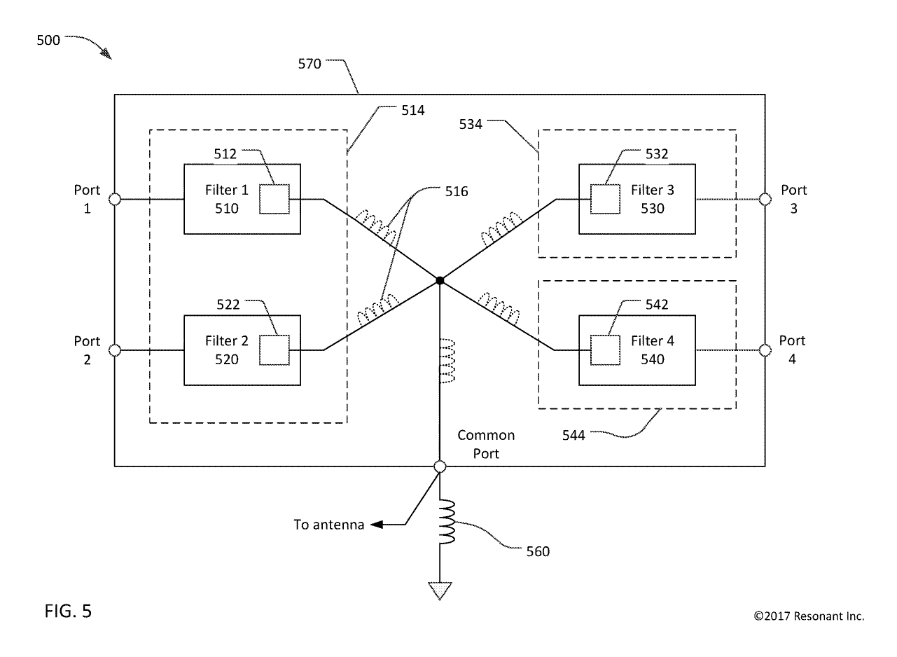

FIG. 5 is a block diagram of an exemplary four-band multiplexer 500 including four band-pass filters 510, 520, 530, 540 and a shunt reactive element 560 (shown as an inductor) connected between a common Port and ground. Each band pass filter 510, 520, 530, 540 terminates in a respective series resonator 512, 522, 532, 542 that connects to the common node 550. Other internal details of the band-pass filters 510, 520, 530, 540 are not shown. Each band-pass filter 510, 520, 530, 540 is designed to appear as approximately and open circuit at the passbands of the other band-pass filters, and each band-pass filter 510, such that phase matching networks between the band-pass filters and the common port are not required.

One, two, three, or four piezo-electric acoustic substrates may be used to build the four band pass filters of a four channel multiplexer. For example, as shown in FIG. 5, filters 510 and 520 are fabricated on a first piezo-electric substrate 514 and filters 530 and 540 are fabricated on separate piezo-electric substrate 534, 544, respectively. The properties of the filters 510, 520, 530, 540 may be optimized by selection of different materials and/or cut angles of the piezo-electric substrates, different resonator geometries, and different fabrication processes (particularly different metal thicknesses). For high performance multiplexers, this leads to the choice of separate substrates for each or multiple sets of filters. It may also be the case that multiple substrates can be of the same material and processed the same, but separate for other reasons (i.e. easy of connection, physical form factors, packaging limitations . . . ). Piezo-electric substrates are anisotropic, and the direction of propagation of the acoustic wave has to be appropriately aligned with the substrate. This can cause issues with the layout of the filters and affect the design of the interconnection.

Whatever the number of substrates used in a multiplexer, the filters must be connected together. This leads to the need for interconnections. For example, the three piezoelectric substrates 514, 534, 544 may be flip-chip mounted on a common substrate 570 within a common package. Pads on each of the piezoelectric substrates may be connected to corresponding pads on the substrate 570 using, for example, solder bumps. The interconnections between the final resonator 512, 522, 532, 542 of each filter and the common port include traces on each piezoelectric substrate, the solder bumps, and traces on the surface of the substrate 570. The overall length of the interconnections may be small compared to the wavelength of RF signals at the frequency of operation of the multiplexer, such that the interconnections may be considered as series inductances 516 rather than transmission lines. The value of the series inductances 516 may be compensated in the design of the filters 510, 520, 530, 540 such that proper phase matching at the common port is maintained.

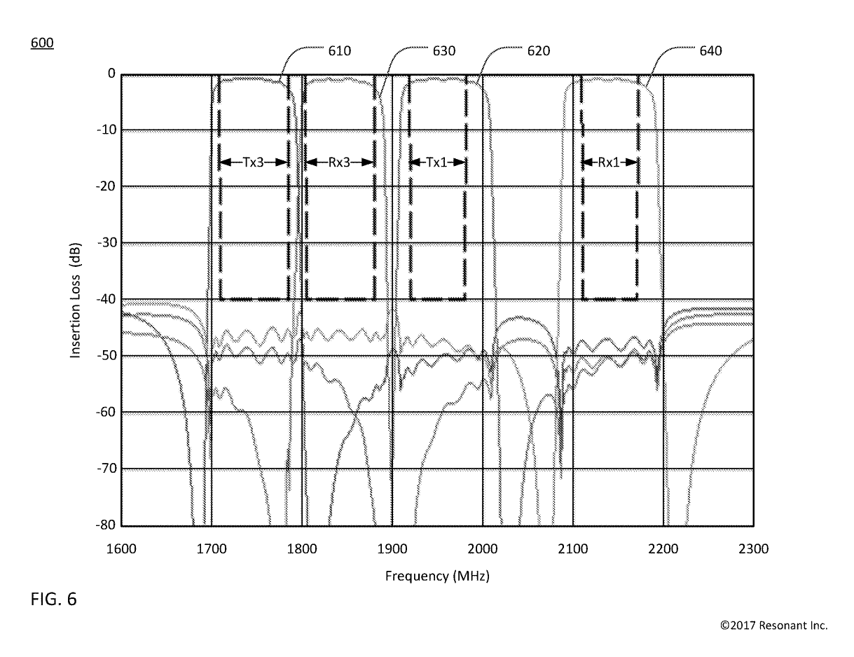

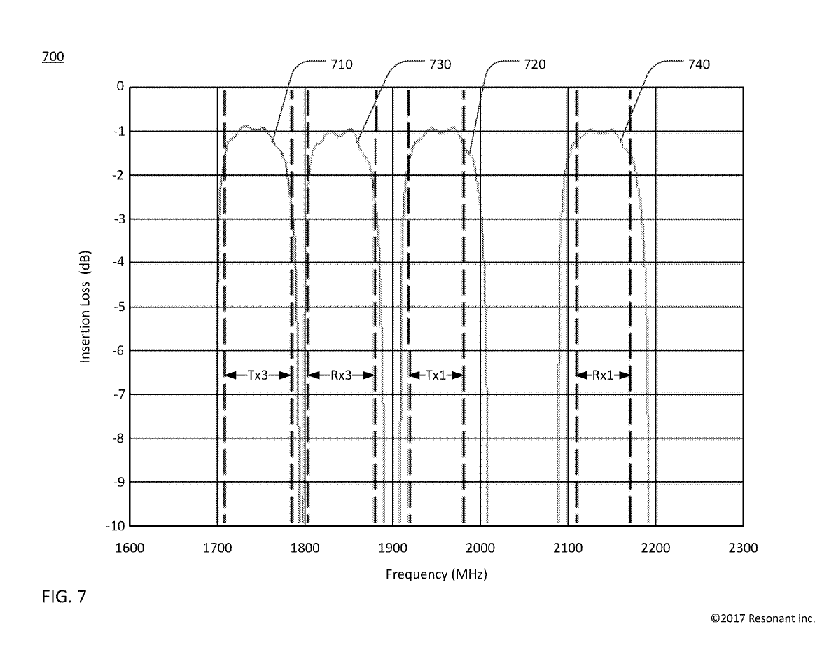

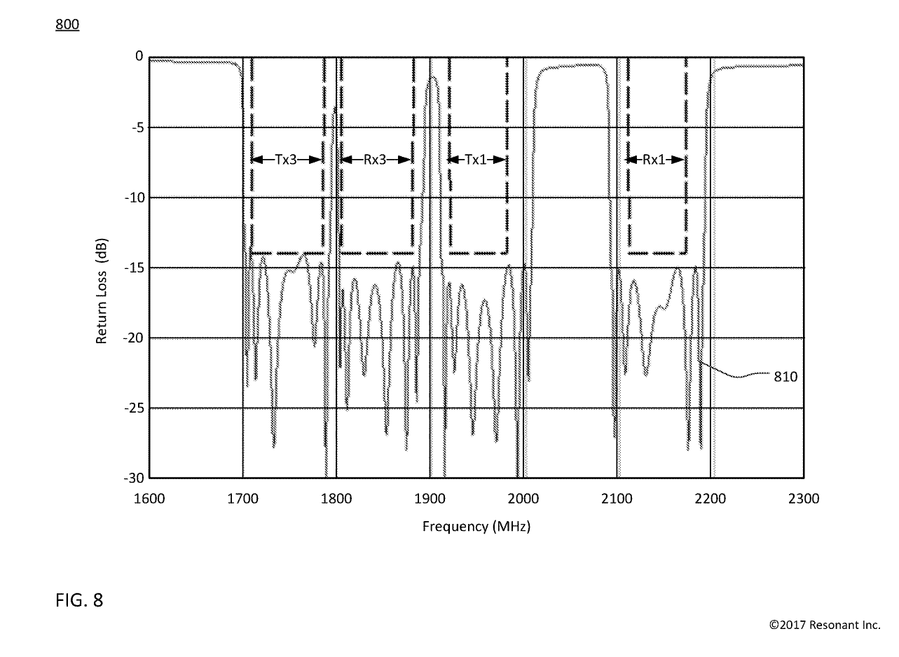

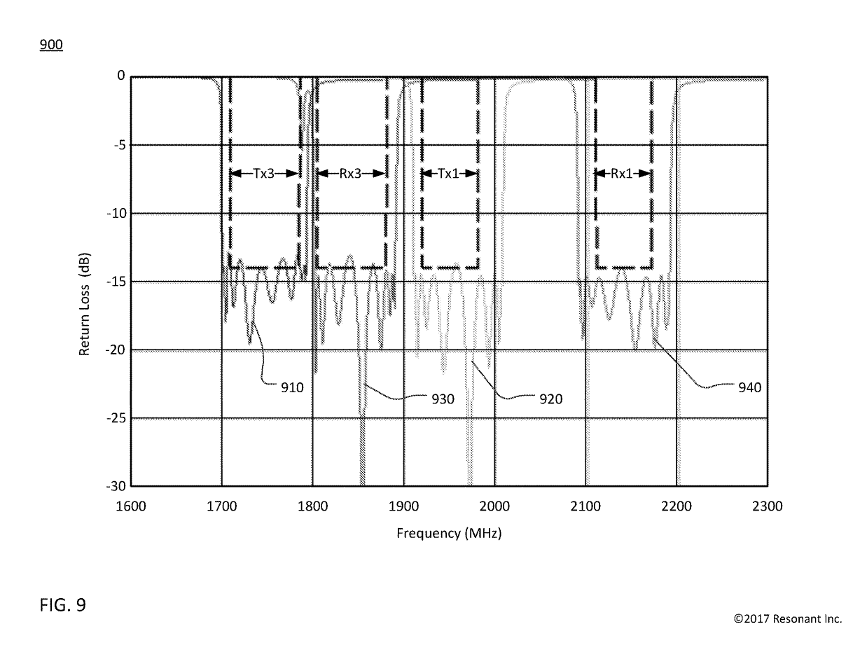

FIG. 6, FIG. 7, FIG. 8, and FIG. 9 are graphs showing the anticipated performance of a specific embodiment of the multiplexer 500 shown in FIG. 5. In the specific embodiment, filter 510 is a Band 3 transmit filter having a passband of 1710 to 1785 MHz. Filter 520 is a Band 1 transmit filter having a passband of 1920 to 1980 MHz. Filter 530 is a Band 3 receive filter having a passband of 1805 to 1880 MHz. Filter 540 is a Band 1 receive filter having a passband of 2110 to 2170 MHz. In the specific embodiment, filters 510, 520, and 540 each include eight resonators and filter 530 includes ten resonators.

The data shown in FIG. 6, FIG. 7, FIG. 8, and FIG. 9 resulted from simulation of the multiplexer using the well-known Butterworth Van Dyke (BVD) electrical model for the acoustic wave resonators. A Band 1/Band 3 transmit/receive multiplexer is an example of a four-band multiplexer. Multiplexers may be used for other frequency bands and for other functions.

FIG. 6 and FIG. 7 are graphs, using different scales for the ordinate (vertical) axis, of the insertion loss from each of the branch ports to the common port of the filter 500. The curves 610 and 710 represent the insertion loss from Port 1 to the common port through filter 510. The curves 620 and 720 represent the insertion loss from Port 2 to the common port through filter 520. The curves 630 and 730 represent the insertion loss from Port 3 to the common port through filter 530. The curves 640 and 740 represent the insertion loss from Port 4 to the common port through filter 540.

FIG. 8 is a graph of the return loss at the common port of the multiplexer 500, which is represented by the curve 810.

FIG. 9 is a graph of the return loss at each of the branch ports of the multiplexer 500. The curve 910 represents the return loss at Port 1. The curve 920 represents the return loss at Port 2. The curve 930 represents the return loss at Port 3. The curve 940 represents the return loss at Port 4.

Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. A radio frequency multiplexer, comprising:
three or more band-pass filters having respective passbands, each band-pass filter comprising two or more acoustic resonators, wherein
a first end of each of the three or more band-pass filters is connected to a respective branch port, and
a second end of each of the three or more band-pass filters is connected to a common node without an intervening phasing network; and
a shunt reactive element connected between the common node and ground.

2. The radio frequency multiplexer of claim 1, wherein
the second end of each or the three or more band-pass filter appears, to the common node, as a substantially open circuit at the frequencies of the passbands of the other band-pass filters.

3. The radio frequency multiplexer of claim 1, further comprising:
one or more packages enclosing the three or more band-pass filters, wherein the shunt reactive element is external to the one or more packages.

4. The radio frequency multiplexer of claim 3, further comprising:
at least one piezoelectric chip, on which at least one of the three or more band-pass filters is fabricated, within each of the one or more packages.

5. The radio frequency multiplexer of claim 1, wherein
the second end of each of the three or more band-pass filters terminates in a series acoustic resonator.

6. A method for designing radio frequency multiplexer having three or more channels, the method comprising:
designing respective band-pass filters for the three or more channels, each band-pass filter meeting respective requirements when a second end of the band-pass filter is connected to a nominal load impedance;
combining models of the band-pass filters to form a model of a hypothetical multiplexer, wherein
a second end of each band-pass filter is connected to a common node with an ideal connection, and
a shunt reactive element and the nominal load impedance are connected, in parallel, between the common node and ground; and
modifying the design of one or more of the band-pass filters to provide an improved multiplexer design where each of the band-pass filters meets the respective requirements when the second end of the band-pass filter is connected to the common node without an intervening phasing network.

7. The method of claim 6, wherein modifying the design of one or more of the band-pass filters further comprises:
modifying the design of one or more of the band-pass filters such that the second end of each of the band-pass filter appears, to the common node, as a substantially open circuit at the frequencies of the passbands of the other band-pass filters.

8. The method of claim 6, further comprising:
converting the improved multiplexer design into a physical design including layout, packaging, and interconnections.

9. The method of claim 8, further comprising:
further modifying the design of one or more of the band-pass filters to compensate for the interconnections.

10. The method of claim 1, wherein designing respective band-pass filters further comprises:
designing band-pass filters with the second end of each band-pass filter terminating in a series acoustic resonator.
